(19) United States
(12) Patent Application Publication
(10) Pub. No.: US 2025/0253223 A1
(43) Pub. Date: Aug. 7, 2025

(54) REDISTRIBUTION SUBSTRATE, MANUFACTURING METHOD OF THE SAME, AND SEMICONDUCTOR PACKAGE INCLUDING THE SAME

(71) Applicant: Samsung Electronics Co., Ltd., Suwon-si (KR)

(72) Inventor: JUNGHOON KANG, Suwon-si (KR)

(21) Appl. No.: 18/885,362

(22) Filed: Sep. 13, 2024

(30) Foreign Application Priority Data
Feb. 7, 2024 (KR) 10-2024-0019065

(51) Int. Cl. H01L 23/498; H01L 21/48; H01L 23/00; H01L 25/18; H05K 1/18

(52) U.S. Cl. CPC H01L 23/49822; H01L 21/4857; H01L 23/49833; H01L 23/49838; H01L 23/49894; H01L 24/08; H01L 24/48; H01L 25/18; H01L 2224/08225; H01L 2224/48225; H01L 2924/1815; H05K 1/181

(57) ABSTRACT

A redistribution substrate includes a first insulating layer, a pad disposed on the first insulating layer and including a groove, a central portion surrounded by the groove, and an edge portion disposed outside the groove, wherein the groove is formed at an upper surface of the pad, a conductive layer disposed on the pad, wherein, when viewed in a plan view, the conductive layer is disposed within an outer boundary of the groove, a second insulating layer disposed on the pad and having a via hole exposing the conductive layer, and a connection terminal disposed within the via hole of the second insulating layer. An outer edge portion of the conductive layer is disposed within groove, and a width of the central portion of the pad is wider than a width of the groove.

### CROSS-REFERENCE TO RELATED APPLICATION

This application claims priority to and the benefit of Korean Patent Application No. 10-2024-0019065 filed in the Korean Intellectual Property Office on Feb. 7, 2024, the entire contents of which are herein incorporated by reference.

### BACKGROUND

### 1. Field

The present disclosure relates to a redistribution substrate, a manufacturing method of the same, and a semiconductor package including the same.

### 2. Description of the Related Art

A semiconductor chip included in a semiconductor package may be electrically connected to an external electronic component through a redistribution substrate and a connection portion.

Cracks may occur in an insulating layer covering and protecting a pad portion of the redistribution substrate, and the cracks may extend into the inside of the semiconductor package.

In addition, when contact characteristics between the pad portion and the insulating layer disposed on the pad portion decrease, the insulating layer may be lifted off.

### SUMMARY

Embodiments attempt to provide a redistribution substrate, a manufacturing method of the same, and a semiconductor package including the same that may prevent cracks from occurring in a redistribution substrate of a semiconductor package and improve contact characteristics between a pad portion and an insulating layer.

However, the problems to be solved by embodiments are not limited to the above-described problem and may be variously extended in a range of technical ideas included in embodiments.

According to an aspect of the present disclosure, a redistribution substrate includes a first insulating layer, a pad disposed on the first insulating layer and including a groove, a central portion surrounded by the groove, and an edge portion disposed outside the groove, wherein the groove is formed at an upper surface of the pad, a conductive layer disposed on the pad, wherein, when viewed in a plan view, the conductive layer is disposed within an outer boundary of the groove, a second insulating layer disposed on the pad and having a via hole exposing the conductive layer, and a connection terminal disposed within the via hole of the second insulating layer. An outer edge portion of the conductive layer is disposed within groove, and a width of the central portion of the pad is wider than a width of the groove.

According to an aspect of the present disclosure, a manufacturing method of a redistribution substrate includes forming a seed layer on a first insulating layer, forming a pad on the seed layer, forming a groove at an upper surface of the pad, wherein the pad includes a central portion surrounded by the groove and an edge portion outside the groove, forming a conductive layer on the groove of the pad and the central portion of the pad surrounded by the groove, forming a second insulating layer having a via hole exposing the conductive layer, and forming a connection terminal within the via hole of the second insulating layer. An outer edge portion of the conductive layer is disposed within groove. A width of the central portion of the pad is wider than a width of the groove.

According to an aspect of the present disclosure, a semiconductor package includes a first redistribution substrate, a second redistribution substrate, and a semiconductor chip disposed between the first redistribution substrate and the second redistribution substrate. The first redistribution substrate includes a first insulating layer; a pad disposed on the first insulating layer and including a groove, a central portion surrounded by the groove, and an edge portion disposed outside the groove, a conductive layer disposed on the pad, wherein, when viewed in a plan view, the entirety of the conductive layer is disposed within an outer boundary of the groove, a second insulating layer disposed on the pad and having a via hole exposing the conductive layer, and a connection terminal disposed within the via hole of the second insulating layer. An outer edge portion of the conductive layer is disposed within groove. A width of the central portion of the pad is wider than a width of the groove.

It is obvious that the effect of the embodiments is not limited to the above-described effect, and may be variously extended without departing from the spirit and scope of the present disclosure.

### BRIEF DESCRIPTION OF THE DRAWINGS

FIG. 1 illustrates a semiconductor package according to an embodiment.

FIG. 2 illustrates a cross-sectional view of a portion of a redistribution substrate of a semiconductor package according to an embodiment.

FIG. 3 illustrates an enlarged view of a portion of FIG. 2.

FIG. 4 to FIG. 6 illustrate top plan views of a portion of a redistribution substrate according to embodiments.

FIG. 7 to FIG. 14 illustrate cross-sectional views of a manufacturing method of a redistribution substrate according to an embodiment.

FIG. 15 illustrates a semiconductor package according to an embodiment.

### DETAILED DESCRIPTION

The present disclosure will be described more fully hereinafter with reference to the accompanying drawings, in which embodiments of the disclosure are shown. As those skilled in the art would realize, the described embodiments may be modified in various different ways, all without departing from the spirit or scope of the present disclosure.

In order to clearly describe the present disclosure, parts or portions that are irrelevant to the description are omitted, and identical or similar constituent elements throughout the specification are denoted by the same reference numerals.

In addition, the accompanying drawings are provided only in order to allow embodiments disclosed in the present specification to be easily understood and are not to be interpreted as limiting the spirit disclosed in the present specification, and it is to be understood that the present disclosure includes all modifications, equivalents, and substitutions without departing from the scope and spirit of the present disclosure.

Further, in the drawings, the size and thickness of each element are arbitrarily illustrated for ease of description, and the present disclosure is not necessarily limited to those illustrated in the drawings. In the drawings, the thicknesses of layers, films, panels, regions, areas, etc., are exaggerated for clarity. In the drawings, for ease of description, the thicknesses of some layers and areas are exaggerated.

It will be understood that when an element such as a layer, film, region, area, or substrate is referred to as being “on” or “above” another element, it can be directly on the other element or intervening elements may also be present. In contrast, when an element is referred to as being “directly on” another element, there are no intervening elements present. Further, in the specification, the word “on” or “above” means disposed on or below the object portion, and does not necessarily mean disposed on the upper side of the object portion based on a gravitational direction.

In addition, unless explicitly described to the contrary, the word “comprise” and variations such as “comprises” or “comprising” will be understood to imply the inclusion of stated elements but not the exclusion of any other elements.

Further, throughout the specification, the phrase “in a plan view” or “on a plane” means viewing a target portion from the top, and the phrase “in a cross-sectional view” or “on a cross-section” means viewing a cross-section formed by vertically cutting a target portion from the side.

Furthermore, throughout the specification, “connected” does not only mean when two or more elements are directly connected, but also when two or more elements are indirectly connected through other elements, and when they are physically connected or electrically connected, and further, it may be referred to by different names depending on a position or function, and may also be referred to as a case in which respective parts that are substantially integrated are linked to each other.

Hereinafter, various embodiments and variations will be described in detail with reference to the drawings.

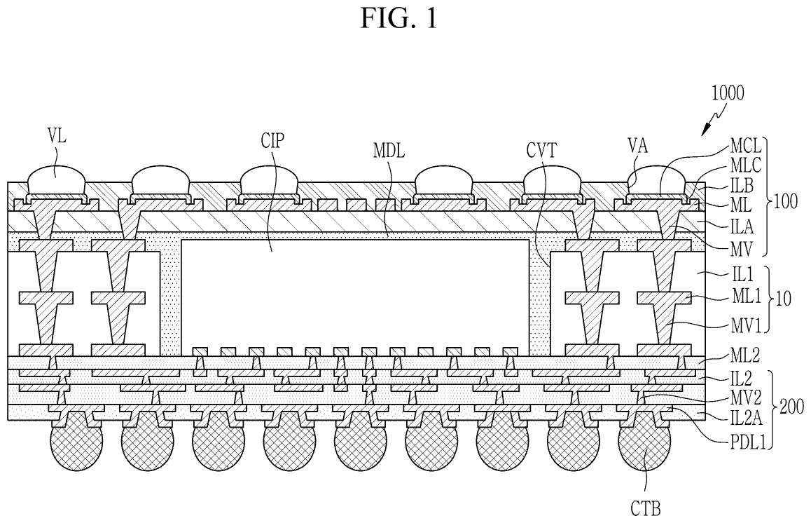

Referring to FIG. 1, a semiconductor package 1000 according to an embodiment may include a first redistribution substrate 100, a second redistribution substrate 200, a connection substrate 10 disposed between the first redistribution substrate 100 and the second redistribution substrate 200, and a semiconductor chip CIP mounted in the connection substrate 10. The semiconductor package 1000 according to the present embodiment may be a lower package.

The connection substrate 10 may have a through hole CVT penetrating the inside thereof, and the semiconductor chip CIP may be mounted in the through hole CVT of the connection substrate 10.

The connection substrate 10 may be disposed on the second redistribution substrate 200, and the first redistribution substrate 100 may be disposed on the connection substrate 10.

The connection substrate 10 may include a base layer IL1, connection layers ML1 that may be at least partially embedded in the base layer IL1, and vias MV1 disposed in the base layer IL1 and connected to the connection layers ML1. Lowermost connection layers ML1 among the connection layers ML1 may be connected to the second redistribution substrate 200, and uppermost connection layers ML1 among the connection layers ML1 may be connected to the first redistribution substrate 100.

The second redistribution substrate 200 may include a plurality of base layers IL2, redistribution layers ML2 that may be at least partially embedded in the plurality of base layers IL2, vias MV2 connected to the redistribution layers ML2, an insulating layer IL2A disposed below the base layers IL2, and connection pads PDL1 connected to the redistribution layers ML2 through a via holes in the insulating layer IL2A.

The plurality of base layers IL2 may include or may be formed of an organic material such as a photo-imageable dielectric (PID) material. The photo-imageable dielectric material may include at least one of, for example, photo-imageable polyimide, polybenzoxazole, phenol-based polymer, and benzocyclobutene-based polymer, but the embodiment is not limited thereto. The number of the plurality of base layers IL2 stacked on each other may be variously changed. For example, the plurality of base layers IL2 may include or may be formed of the same material, and the interface between the plurality of adjacent base layers IL2 may not be distinguished.

Solder balls CTB may be disposed on a lower surface of the second redistribution substrate 200, and the solder balls CTB may be connected to the connection pads PDL1. The solder balls CTB may include or may be formed of a solder material. The solder material may include, for example, tin, bismuth, lead, silver, or an alloy thereof, but the embodiment is not limited thereto.

A molding layer MDL may fill a space between the semiconductor chip CIP and the connection substrate 10, a space between the semiconductor chip CIP and the second redistribution substrate 200, and a space between the connection substrate 10 and the first redistribution substrate 100. The molding layer MDL may include an adhesive insulating film such as an Ajinomoto build-up film (ABF). In an embodiment, the molding layer MDL may include or may be formed of an insulating polymer such as an epoxy-based polymer, but the embodiment is not limited thereto.

The first redistribution substrate 100 may be disposed on the molding layer MDL and the connection substrate 10.

The first redistribution substrate 100 may include a first insulating layer ILA, pad layers ML (i.e., pads) disposed on the first insulating layer ILA, cover layers MCL (i.e., conductive layers) disposed on the pad layers ML, a second insulating layer ILB disposed on the first insulating layer ILA and having via holes VA overlapping the pad layers ML (i.e., exposing the cover layers MCL), connection portions VL (i.e., connection terminals) disposed in the via holes VA of the second insulating layer ILB and connected to the pad layers ML through the cover layers MCL, and vias MV formed in the first insulating layer ILA and connecting the pad layers ML to connection layers ML1, respectively.

A groove portion MLC (i.e., a groove) may be disposed at a region adjacent to an edge of each of the pad layers ML. For example, the groove portion MLC may be formed at an upper surface of each of the pad layers ML.

The connection portions VL may be connected to an upper semiconductor package to be described later. The semiconductor package 1000, which is a lower semiconductor package, and the upper semiconductor package may be electrically connected with each other through connection portions VL.

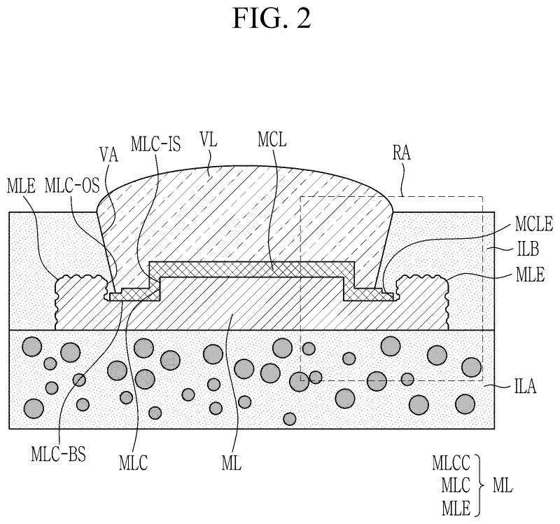

Then, the first redistribution substrate of the semiconductor package according to the embodiment will be described in more detail with reference to FIG. 2 to FIG. 6.

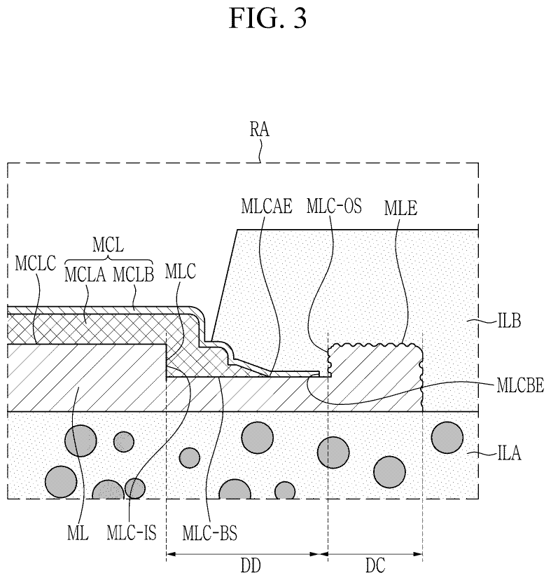

First, the redistribution substrate according to the embodiment will be described with reference to FIG. 2 and FIG. 3. FIG. 2 illustrates a cross-sectional view of a portion of the redistribution substrate according to the embodiment, and FIG. 3 illustrates an enlarged view of a portion of FIG. 2.

FIG. 2 and FIG. 3 illustrate one of a plurality of pad layers ML of the first redistribution substrate 100 of FIG. 1.

Referring to FIG. 2, the redistribution substrate according to the present embodiment may include the first insulating layer ILA, the pad layer ML disposed on the first insulating layer ILA, the cover layer MCL disposed on the pad layer ML, the second insulating layer ILB disposed on the first insulating layer ILA and having the via hole VA overlapping the pad layer ML, and the connection portion VL disposed in the via hole VA and connected to the pad layer ML through the cover layer MCL. The via hole VA may expose the cover layer MCL.

The first insulating layer ILA may include or may be formed of an epoxy resin and an inorganic filler, but the embodiment is not limited thereto.

The pad layer ML may be disposed on the first insulating layer ILA.

The pad layer ML may include or may be formed of metal. For example, the pad layer ML may include or may be formed of copper (Cu), but the embodiment is not limited thereto.

The pad layer ML may include the groove portion MLC formed at a region adjacent to the edge of the pad layer ML. The pad layer ML may include a central portion MLCC surrounded by the groove portion MLC and an edge portion MLE disposed outside the groove portion MLC.

The groove portion MLC of the pad layer ML may be disposed along the edge of the pad layer ML.

A width of the groove portion MLC of the pad layer ML may be smaller than a width of the central portion MLCC surrounded by the groove portion MLC of the pad layer ML. In an embodiment, the widths of the groove portion MLC and the central portion MLCC may be measured in a radial direction extend outwardly from a center of the pad layer ML.

A ratio of a depth of the groove portion MLC of the pad layer ML to a thickness of the central portion MLCC of the pad layer ML may be about 0.4 to about 0.6. For example, the thickness of the central portion MLCC of the pad layer ML may be about 6 μm to about 12 μm, and the depth of the groove portion MLC may be about 4 μm to about 6 μm, but the embodiment is not limited thereto. The groove portion MLC may include a bottom surface MLC-BS, an inner sidewall MLC-IS adjacent to the central portion MLCC, and an outer sidewall MLC-OS adjacent to the edge portion MLE. The inner sidewall MLC-IS may connect an upper surface of the central portion MLCC to the bottom surface MLC-BS of the groove portion MLC. The outer sidewall MLC-OS may connect an upper surface of the edge portion MLE to the bottom surface MLC-BS of the groove portion MLC. The bottom surface MLC-BS of the groove portion MLC may be disposed at a vertical level between the upper surface of the pad layer ML and a lower surface thereof. In an embodiment, the outer sidewall MLC-OS may have a surface roughness greater than a surface roughness of the inner sidewall MLC-IS to provide an increased contact area between the edge portion MLE of the pad layer ML and the second insulating layer ILB.

Referring to FIG. 3, a width DD of the groove portion MLC of the pad layer ML may be equal to or greater than a width DC of the edge portion MLE of the pad layer ML. For example, the width DD of the groove portion MLC of the pad layer ML may be about 30 μm to about 60 μm, and the width DC of the edge portion MLE of the pad layer ML may be about 20 μm to about 30 μm, but the embodiment is not limited thereto.

The surface roughness of the edge portion MLE of the pad layer ML may be greater than that of the center portion MLCC of the pad layer ML. The surface roughness of the edge portion MLE of the pad layer ML may be greater than that of the groove portion MLC of the pad layer ML. In other words, a surface area of the edge portion MLE and a first portion of the groove portion MLC adjacent to the edge portion MLE may increase compared to a surface area of the central portion MLCC and a second portion of the groove portion MLC. The first portion of the groove portion MLC may include a portion of the groove portion MLC not covered with the cover layer MCL which corresponds to the outer sidewall MLC-OS of the groove portion MLC and a portion of the bottom surface MCL-BS of the groove portion MLC. The portion of the bottom surface MCL-BS of the groove portion MLC may be adjacent to the outer sidewall MLC-OS of the groove portion MLC. The second portion of the groove portion MLC may include the other portion of the bottom surface MLC-BS of the groove portion MLC and the inner sidewall MLC-IS of the groove portion MLC. In an embodiment, the outer sidewall MLC-OS may be seen as a part of the edge portion MLE. The cover layer MCL may cover the central portion MLCC and the second portion of the groove portion MLC, exposing the edge portion MLE and the first portion of the groove portion MLC. In an embodiment, the edge portion MLE of the pad layer ML and the first portion of the groove portion MLC may have an uneven surface so that the surface roughness of the edge portion MLE may be greater than the surface roughness of the central portion MLCC and second portion of the groove portion MLC.

As shown in FIG. 1, the redistribution substrate according to the present embodiment may further include the via MV of the first insulating layer ILA, and the pad layer ML may be connected to the via MV.

The cover layer MCL may be disposed on the pad layer ML. The cover layer MCL may be referred to as an under bump metal or an under bump metal layer.

An edge end MCLE of the cover layer MCL may be disposed in the groove MLC of the pad layer ML. The edge end MCLE of the cover layer MCL may be disposed in the groove MLC of the pad layer ML, and may not extend up to the edge portion MLE of the pad layer ML. In an embodiment, the edge end MCLE may be spaced apart from the outer sidewall MLC-OS of the groove portion MLC, without contacting the outer sidewall MLC-OS of the groove portion MLC. In an embodiment, the edge end MCLE may not contact an upper surface of the edge portion MLE.

The cover layer MCL may include nickel (Ni) and gold (Au), but the embodiment is not limited thereto.

The cover layer MCL may be disposed on the pad layer ML to serve as a barrier layer that prevents a material contained in the pad layer ML, for example copper, from diffusing into the connection portion VL disposed on the pad layer ML, and it may improve the bonding properties between the pad layer ML and the connection portion VL.

The cover layer MCL may include an alloy including nickel and gold. In an embodiment, the cover layer MCL may be a double layer including a nickel layer and a gold layer, which will be described with reference to FIG. 3.

Referring to FIG. 3, the cover layer MCL may include a lower layer MCLA including nickel and an upper layer MCLB including gold. In an embodiment, the lower layer MCLA may include or may be formed of nickel, and the upper layer MCLB may include or may be formed of gold. The lower layer MCLA may serve as a diffusion barrier which prevents copper of the pad layer ML from diffusing into the connection portion VL. The thickness of the lower layer MCLA may be greater than that of the upper layer MCLB. For example, the thickness of the lower layer MCLA may be from about 2 μm to about 8 μm, and the thickness of the upper layer MCLB may be from about 0.32 μm to about 7 μm, but the embodiment is not limited thereto.

An edge end MCLAE of the lower layer MCLA of the cover layer MCL may be covered by the upper layer MCLB, but the embodiment is not limited thereto. In an embodiment, an edge end MLCBE of the upper layer MLCB may extend beyond the edge end MCLBE of the lower layer MCLB toward the outer sidewall MLC-OS of the groove portion MLC and may be spaced apart from the outer sidewall MLC-OS of the groove portion MLC.

The thickness of the cover layer MCL may be smaller than the thickness of the pad layer ML. For example, the thickness of the cover layer MCL may be from about 2 μm to about 9 μm, but the embodiment is not limited thereto.

The second insulating layer ILB may be disposed on the pad layer ML. The second insulating layer ILB may have a via hole VA overlapping the pad layer ML.

The via hole VA of the second insulating layer ILB may overlap the central portion MLCC of the pad layer ML and a portion of the groove portion MLC of the pad layer ML.

The via hole VA of the second insulating layer ILB may expose the cover layer MCL.

An edge of a sidewall of the via hole VA of the second insulating layer ILB may overlap the cover layer MCL, and the second insulating layer ILB may cover and protect an end portion of the cover layer MCL disposed in the groove MLC of the pad layer ML and the edge portion MLE of the pad layer ML. In an embodiment, the second insulating layer ILB may contact the outer sidewall MLC-OS of the groove portion MLC, and a portion, adjacent to the outer sidewall MLC-OS of the groove portion, of the bottom surface MLC-BS of the groove portion MLC. In an embodiment, a portion of the second insulating layer ILB may be disposed in a space between the outer sidewall MLC-OS and the end portion of the cover layer MCL and contact the portion of the bottom surface MLC-BS of the groove portion MLC.

The surface roughness of the edge portion MLE of the pad layer ML not covered by the cover layer MCL may be greater than the surface roughness of the central portion MLCC and the groove portion MLC of the pad layer ML covered by the cover layer MCL.

As the surface roughness of the edge portion MLE of the pad layer ML is large, the contact characteristic between the second insulating layer ILB disposed on the edge portion MLE of the pad layer ML and the edge portion MLE of the pad layer ML may be improved. For example, a contact surface between the second insulating layer ILB disposed on the edge portion MLE of the pad layer ML and the edge portion MLE of the pad layer ML may increase, thereby increasing adhesion therebetween and preventing lifting-off of the second insulating layer ILB.

The second insulating layer ILB covers and protects the edge portion MLE of the pad layer ML to prevent the pad layer ML from being exposed to the outside of the redistribution substrate, thereby preventing the material included in the pad layer ML from being diffused to the outside and preventing the pad layer ML from being oxidized.

The connection portion VL may be disposed in the via hole VA of the second insulating layer ILB, and the connection portion VL may electrically connect the redistribution substrate to an external element such as an upper package through the cover layer MCL and the pad layer ML. In an embodiment, the connection portion VL may be a solder ball or a solder bump.

Generally, when the cover layer MCL is formed on the pad layer ML, the cover layer MCL may protrude outward from the edge of the pad layer ML. Due to the cover layer MCL protruding outside the edge of the pad layer ML, an undercut may occur in the pad layer ML under the cover layer MCL during a subsequent etching process, thus a crack may occur at the interface between the cover layer MCL and the second insulating layer ILB, and the crack may propagate into the redistribution substrate.

However, according to the embodiment, the pad layer ML may include the groove portion MLC formed at the edge thereof, and the edge end MCLE of the cover layer MCL, which is disposed on the pad layer ML and covers and protects the pad layer ML and prevents diffusion of materials included in the pad layer ML, may be disposed within the groove portion MLC of the pad layer ML. As such, the edge end MCLE of the cover layer MCL may be disposed within the groove MLC of the pad layer ML, and may not extend up to the edge portion MLE of the pad layer ML. In an embodiment, the entirety of the cover layer MCL may be disposed in an outer boundary of the groove portion MLC. The outer boundary of the groove portion MLC may correspond to the outer sidewall MLC-OS of the groove portion MLC. The edge end MCLE of the cover layer MCL may be spaced apart from the outer sidewall MLC-OS of the groove portion MLC without contacting the outer sidewall MLC-OS. In an embodiment, the edge end MCLE of the cover layer MCL may contact the outer sidewall MLC-OS without being disposed on an upper surface of the edge portion MLE.

Therefore, the cover layer MCL disposed on the pad layer ML does not protrude laterally than the pad layer ML, and may prevent cracks that may occur at the interface between the cover layer MCL and the second insulating layer ILB. For example, the groove portion MLC of the pad layer ML may prevent the cover layer MCL from extend beyond an outer boundary of the pad layer ML, thereby preventing cracks from occurring at the interface between the cover layer MCL and the second insulating layer ILB.

According to the embodiment, the surface roughness of the edge portion MLE of the pad layer ML not covered by the cover layer MCL may be greater than the surface roughness of the central portion MLCC and the groove portion MLC of the pad layer ML covered by the cover layer MCL. Therefore, the contact characteristic between the second insulating layer ILB having the via hole VA overlapping the pad layer ML and the edge portion MLE of the pad layer ML may be improved.

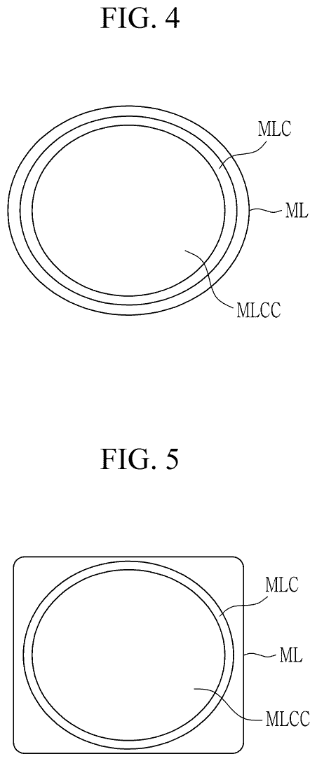

Then, the shape of the pad layer ML according to embodiments will be described with reference to FIG. 4 to FIG. 6 together with FIG. 2 and FIG. 3. FIG. 4 to FIG. 6 illustrate top plan views of a portion of a redistribution substrate according to embodiments. FIG. 4 to FIG. 6 illustrate pad layers of a redistribution substrate according to embodiments.

Referring to FIG. 4, the pad layer ML of the redistribution substrate according to an embodiment may have a circular planar shape, and the groove portion MLC of the pad layer ML may be disposed adjacent to the edge of the pad layer ML, and may be ring-shaped. The groove portion MLC may surround the central portion MLCC of the pad layer ML. For example, the groove portion MLC may be a closed loop shape when viewed in a plan view. The pad layer ML of the redistribution substrate according to an embodiment may have an elliptical shape.

Referring to FIG. 5, the pad layer ML of the redistribution substrate according to the embodiment may have a quadrangular planar shape with rounded corners, and the groove portion MLC of the pad layer ML may be disposed adjacent to the edge of the pad layer ML, and may have a ring shape. The groove portion MLC may surround the central portion MLCC of the pad layer ML.

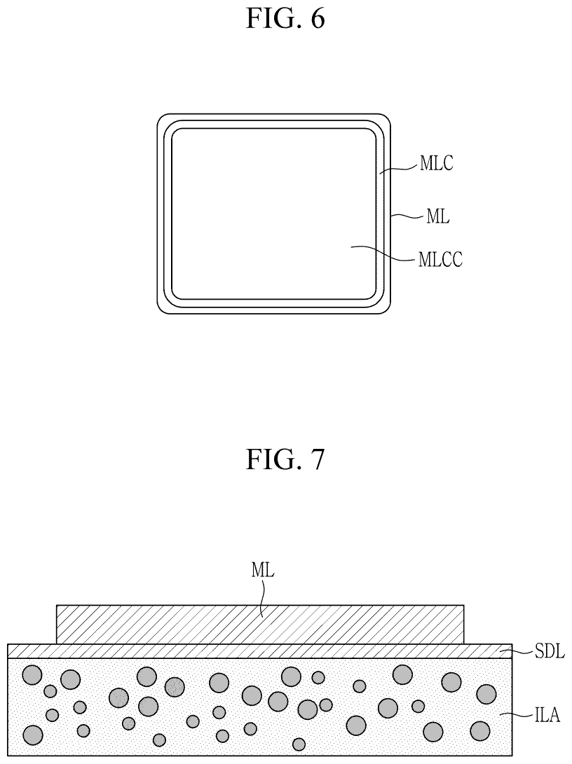

Referring to FIG. 6, the pad layer ML of the redistribution substrate according to an embodiment may have a quadrangular planar shape with rounded corners, and the groove portion MLC of the pad layer ML may be disposed adjacent to the edge of the pad layer ML, and may have a quadrangular ring shape. The groove portion MLC may surround the central portion MLCC of the pad layer ML.

FIG. 4 to FIG. 6 illustrate examples of the planar shape of the pad layer ML of the redistribution substrate according to embodiments, and the embodiments are not limited thereto, and the planar shape of the pad layer ML of the redistribution substrate may be variously modified.

A method of manufacturing the redistribution substrate according to the embodiment will be described with reference to FIG. 7 to FIG. 14 together with FIG. 1 to FIG. 6. FIG. 7 to FIG. 14 illustrate cross-sectional views of a manufacturing method of a redistribution substrate according to an embodiment.

Referring to FIG. 7, a seed layer SDL may be stacked on the first insulating layer ILA, and the pad layer ML may be formed on the seed layer SDL. For example, after forming a blocking pattern on a portion of the seed layer SDL, plating is performed on the seed layer SDL using the blocking pattern as a mask to form the pad layer ML having a desired shape at a desired position.

The seed layer SDL and the pad layer ML may include or may be formed of metal, for example, copper, but the embodiment is not limited thereto.

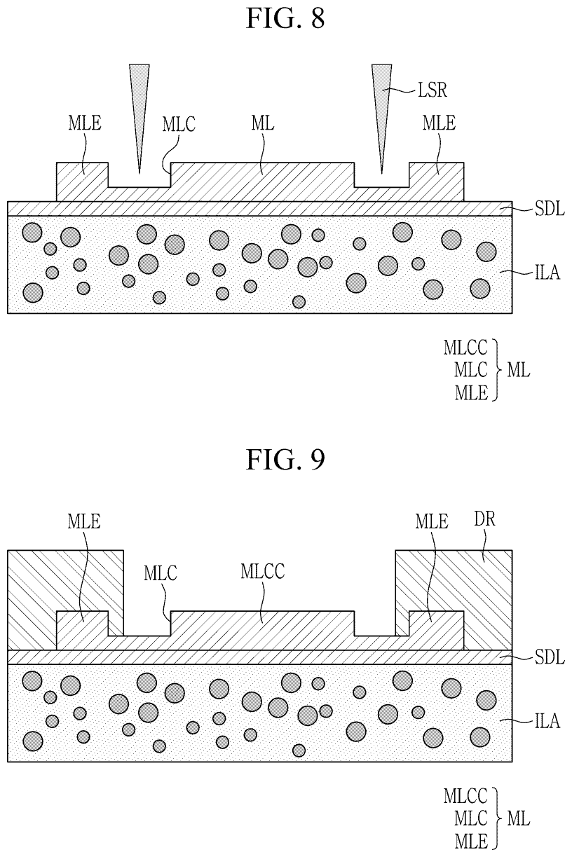

Referring to FIG. 8, the groove portion MLC may be formed by removing a portion of the upper surface of the pad layer ML along the edge portion MLE of the pad layer ML.

The groove portion MLC may be formed using a laser LSR. The wavelength of the laser LSR may be about 350 nm to about 1100 nm, for example, the wavelength of the laser LSR may be about 355 nm (DPSS UV), about 532 nm (DPSS Green), and about 1064 nm (DPSS IR), but the embodiment is not limited thereto. In addition, the laser LSR may be a carbon dioxide laser (CO₂ laser), but the embodiment is not limited thereto.

The pad layer ML may include the groove portion MLC formed along the edge thereof, the central portion MLCC surrounded by the groove portion MLC, and the edge portion MLE disposed outside the groove portion MLC. For example, the groove portion MLC may be formed at an upper surface of the pad layer ML, defining the inside of the groove portion MLC as the central portion MLCC and the outside of the groove portion MLC as the edge portion MLE. A bottom surface of the groove portion MLC may be disposed at a vertical level between the upper surface of the pad layer ML and a lower surface thereof.

Referring to FIG. 9, a blocking layer DR may be formed to cover the edge portion MLE of the pad layer ML. The blocking layer DR may cover a portion (i.e., a first portion) of the groove portion MLC. The central portion MLCC of the pad layer ML and the other portion (i.e., a second portion) of the groove portion MLC of the pad layer ML may be exposed without being covered by the blocking layer DR.

The blocking layer DR may be a dry film, but the embodiment is not limited thereto.

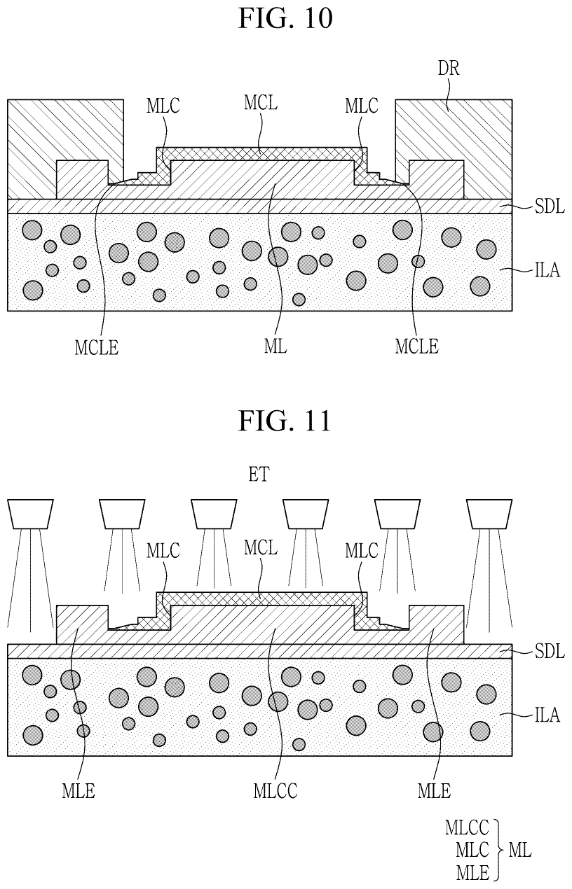

Referring to FIG. 10, the cover layer MCL may be formed in the central portion MLCC of the pad layer ML exposed without being covered by the blocking layer DR and the other portion of the groove portion MLC of the pad layer ML by using the blocking layer DR as a mask.

The cover layer MCL may be formed by plating a metal layer on the pad layer ML. The cover layer MCL may include or may be formed of nickel and gold.

As illustrated in FIG. 3, the cover layer MCL may include the lower layer MCLA and the upper layer MCLB disposed on the lower layer MCLA, the lower layer MCLA may include nickel, and the upper layer MCLB may include gold, but the embodiment is not limited thereto. The thickness of the lower layer MCLA may be greater than the thickness of the upper layer MCLB, and the upper layer MCLB may cover the lower layer MCLA, but the embodiment is not limited thereto.

When the cover layer MCL is formed, the plating metal may extend along the lower side of the edge of the blocking layer DR, and thus an edge end of the cover layer MCL may be formed up to the lower side of the edge of the blocking layer DR if no stopping obstacle such as groove portion exists. For example, the edge end of the cover layer MCL may be disposed between the lower side of the blocking layer DR and the bottom surface of the groove portion MLC.

However, since the edge end of the blocking layer DR is disposed within the groove portion MLC of the pad layer ML, even if the edge end MCLE of the cover layer MCL is formed up to the lower side of the edge of the blocking layer DR, the edge end MCLE of the cover layer MCL may be disposed within the groove portion MLC of the pad layer ML, and the edge end MCLE of the cover layer MCL may not protrude up to the edge portion MLE of the pad layer ML. The groove portion MLC may serve to prevent the cover layer MCL from extending beyond the groove portion MLC.

Referring to FIG. 11, the blocking layer DR may be removed, and the seed layer SDL that does not overlap the pad layer ML may be removed through an etching process ET.

The etching process ET may be performed by spraying an etchant containing about 10% or less of sulfuric acid using in-line equipment, but the embodiment is not limited thereto.

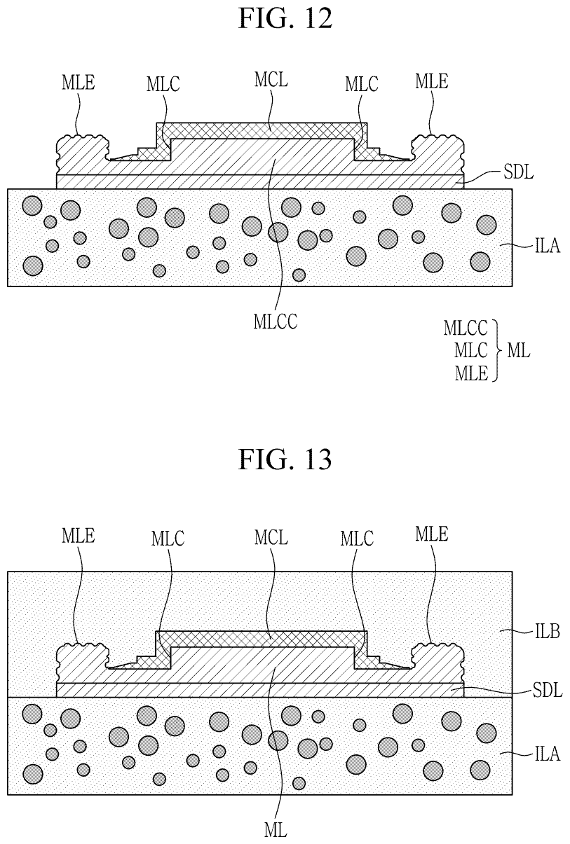

As illustrated in FIG. 12, when the seed layer SDL is removed through the etching process ET, a portion of the surface of the edge portion MLE of the pad layer ML, which is not covered with the cover layer MCL, is etched together, so that the surface roughness of the edge portion MLE of the pad layer ML may be greater than that of the central portion MLCC and the groove portion MLC of the pad layer ML covered by the cover layer MCL. In other words, a surface area of the edge portion MLE and the first portion of the groove portion MLC which are not covered with the cover layer MCL may increase compared to a surface area of the central portion MLCC and the second portion of the groove portion MLC which are covered with the cover layer MCL. In an embodiment, the edge portion MLE of the pad layer ML and the first portion of the groove portion MLC may have an uneven surface so that the surface roughness of the edge portion MLE may be greater than the surface roughness of the central portion MLCC.

Since the edge end MCLE of the cover layer MCL may be disposed in the groove portion MLC of the pad layer ML, and the edge end MCLE of the cover layer MCL does not protrude up to the edge portion MLE of the pad layer ML, an undercut may not be formed at the edge portion MLE of the pad layer ML. Therefore, cracks that may occur at the interface between the cover layer MCL and the second insulating layer ILB may be prevented.

Referring to FIG. 13, the second insulating layer ILB may be stacked on the cover layer MCL and the edge portion MLE of the pad layer ML. As the surface roughness of the edge portion MLE of the pad layer ML is large, the contact characteristic between the second insulating layer ILB disposed on the edge portion MLE of the pad layer ML and the edge portion MLE of the pad layer ML may be improved. For example, a contact surface between the second insulating layer ILB and the edge portion MLE may increase, thereby increasing adhesion of the second insulating layer ILB to the edge portion MLE. In addition, since a portion of the second insulating layer ILB is disposed in the groove portion MLC, interlocking between the second insulating layer ILB and the pad layer ML may be formed, which may prevent the second insulating layer ILB from lifting-off from the pad layer ML.

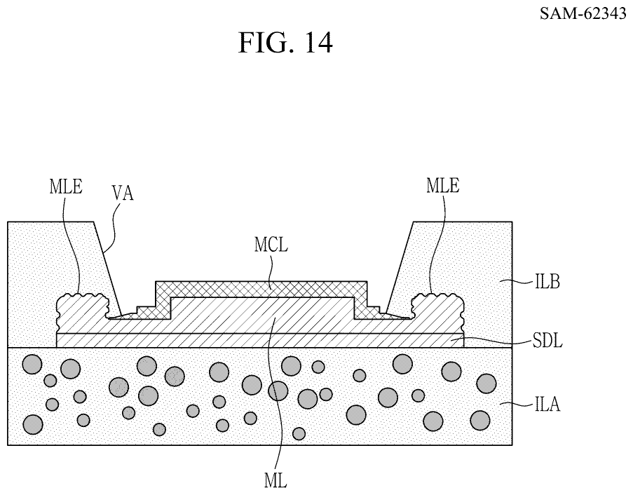

As illustrated in FIG. 14, by photo-etching the second insulating layer ILB, the via hole VA exposing the cover layer MCL disposed on the pad layer ML may be formed in the second insulating layer ILB.

Subsequently, the connection portion VL may be formed in the via hole VA to form the redistribution substrate according to the embodiment described with reference to FIG. 1 to FIG. 6. In an embodiment, the connection portion VL may include or may be formed of a solder ball or a solder bump.

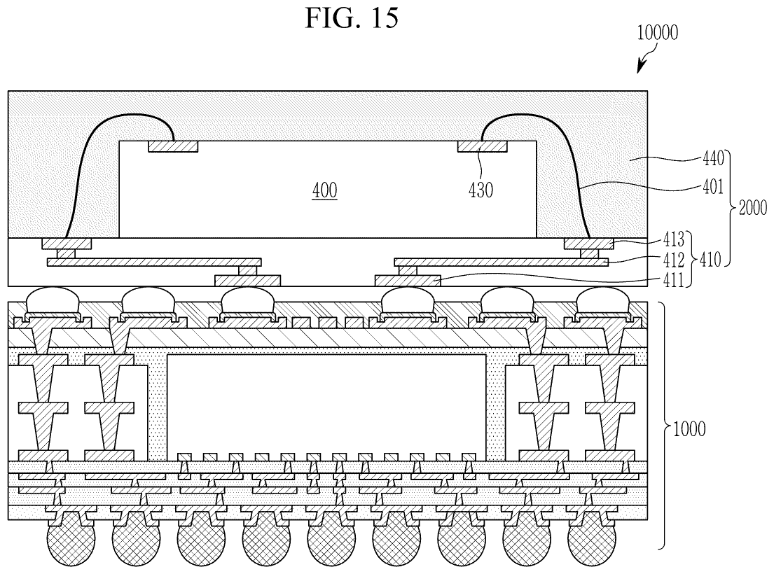

A semiconductor package 10000 according to an embodiment will be described with reference to FIG. 15. FIG. 15 illustrates a cross-sectional view of a semiconductor package according to an embodiment.

Referring to FIG. 15, the semiconductor package 10000 according to an embodiment may include a lower semiconductor package 1000 and an upper semiconductor package 2000.

The lower semiconductor package 1000 may be substantially the same as the semiconductor package 1000 previously described with reference to FIG. 1. For example, the lower semiconductor package 1000 may include the first redistribution substrate 100 and the second redistribution substrate 200, the connection substrate 10 disposed between the first redistribution substrate 100 and the second redistribution substrate 200, and the semiconductor chip CIP mounted in the connection substrate 10.

As previously described with reference to FIG. 2 and FIG. 3, the first redistribution substrate 100 may include the first insulating layer ILA, the pad layer ML disposed on the first insulating layer ILA, the cover layer MCL disposed on the pad layer ML, the second insulating layer ILB disposed on the first insulating layer ILA and having the via hole VA overlapping the pad layer ML, and the connection portion VL disposed in the via hole VA and connected to the pad layer ML through the cover layer MCL. The pad layer ML may include the groove portion MLC formed at a region adjacent to the edge of the pad layer ML, and the cover layer MCL may be disposed on the pad layer ML.

The edge end MCLE of the cover layer MCL may be disposed in the groove MLC of the pad layer ML. The edge end MCLE of the cover layer MCL may be disposed in the groove MLC of the pad layer ML, and may not extend up to the edge portion MLE of the pad layer ML. The surface roughness of the edge portion MLE of the pad layer ML may be greater than a surface roughness of the center portion MLCC of the pad layer ML. The surface roughness of the edge portion MLE of the pad layer ML may be greater than a surface roughness of the groove portion MLC of the pad layer ML.

The upper semiconductor package 2000 may include an upper substrate 410, an upper semiconductor chip 400, and an upper molding film 440.

The upper substrate 410 may be a printed circuit board (PCB) or a redistribution layer.

A first metal pad 411 and a second metal pad 413 may be disposed on the lower surface and the upper surface of the upper substrate 410, respectively.

A metal wire 412 may be disposed in the upper substrate 410, and the metal wiring 412 may electrically connect the first metal pad 411 and the second metal pad 413 with each other.

The upper semiconductor chip 400 may include a chip pad 430.

The upper semiconductor chip 400 may be a different type of semiconductor chip than the semiconductor chip CIP of the lower semiconductor package 1000. For example, the upper semiconductor chip 400 may be a memory chip, but the embodiment is not limited thereto.

A bonding wire 401 may be disposed on the upper semiconductor chip 400, and the bonding wire 401 may electrically connect the chip pad 430 of the upper semiconductor chip 400 to the second metal pad 413.

Unlike shown, the bonding wire 401 may be omitted, and the upper semiconductor chip 400 may be mounted on the upper substrate 410 using a flip chip method. For example, upper bumps (not shown) may be disposed between the upper substrate 410 and the upper semiconductor chip 400, and the upper substrate 410 and the upper semiconductor chip 400 may be electrically connected with each other through the upper bumps. In this case, the chip pad 430 of the upper semiconductor chip 400 may be disposed on the lower surface of the upper semiconductor chip 400.

The upper semiconductor package 2000 may further include the upper molding film 440. The upper molding film 440 may be disposed on the upper substrate 410 and may cover the upper semiconductor chip 400. The upper molding film 440 may cover the bonding wire 401. The upper molding film 440 may include or may be formed of an insulating polymer such as an epoxy-based molding compound, but the embodiment is not limited thereto. The upper molding film 440 may be omitted.

Although not shown, the upper semiconductor package 2000 may further include a heat dissipation structure (not shown). The heat dissipation structure may be disposed on the upper surface of the upper semiconductor chip 400 and the upper surface of the upper molding film 440. The heat dissipation structure may include, for example, a heat sink, a heat slug, or a thermal interface material (TIM) layer, and the heat dissipation structure may include a metal, but the embodiment is not limited thereto.

The first metal pad 411 of the upper substrate 410 may be electrically connected to the connection portion VL of the lower semiconductor package 1000, and thus the lower semiconductor package 1000 and the upper semiconductor package 2000 may be electrically connected with each other.

While this disclosure has been described in connection with what is presently considered to be practical embodiments, it is to be understood that the disclosure is not limited to the disclosed embodiments, but, on the contrary, is intended to cover various modifications and equivalent arrangements included within the spirit and scope of the appended claims.

What is claimed is:

1. A redistribution substrate comprising:
a first insulating layer;
a pad layer disposed on the first insulating layer and including a groove portion, a central portion surrounded by the groove portion, and an edge portion disposed outside the groove portion, wherein the groove portion is disposed at an upper surface of the pad layer;
a cover layer disposed on the pad layer, wherein, when viewed in a plan view, the cover layer is disposed within an outer boundary of the groove portion;
a second insulating layer disposed on the pad layer and having a via hole overlapping the pad layer; and
a connection portion disposed within the via hole of the second insulating layer,
wherein an outer edge portion of the cover layer is disposed within groove portion, and
a width of the central portion of the pad layer is wider than a width of the groove portion.

2. The redistribution substrate of claim 1,
wherein a surface roughness of the edge portion of the pad layer is greater than a surface roughness of the central portion of the pad layer.

3. The redistribution substrate of claim 2,
wherein the cover layer is disposed on the central portion and at least a portion, adjacent to the central portion, of the groove portion, and
wherein the outer edge portion of the cover layer is spaced apart from an outer sidewall of the groove portion that is adjacent to the edge portion of the pad layer.

4. The redistribution substrate of claim 3,
wherein the second insulating layer covers the edge portion of the pad layer.

5. The redistribution substrate of claim 4,
wherein the second insulating layer covers the outer edge portion of the cover layer.

6. The redistribution substrate of claim 5, further comprising:
a seed layer disposed between the first insulating layer and the pad layer.

7. The redistribution substrate of claim 1,
wherein the pad layer includes copper, and
wherein the cover layer includes nickel and gold.

8. The redistribution substrate of claim 7,
wherein the cover layer includes a lower layer and an upper layer disposed on the lower layer, and
wherein the lower layer includes nickel and the upper layer includes gold.

9. The redistribution substrate of claim 8,
wherein an edge end of the lower layer is covered with the upper layer,
wherein the edge end of the lower layer is spaced apart from an outer sidewall of the groove portion which is adjacent to the edge portion of the pad layer, and
wherein an edge end of the upper layer extends beyond the edge end of the lower layer toward the outer sidewall of the groove portion and is spaced apart from the outer sidewall of the groove portion.

10. The redistribution substrate of claim 9,
wherein a thickness of the lower layer is greater than a thickness of the upper layer.

11. The redistribution substrate of claim 1,
wherein the width of the groove portion is equal to or greater than a width of the edge portion.

12. A manufacturing method of a redistribution substrate comprising:
forming a seed layer on a first insulating layer;
forming a pad layer on the seed layer;
forming a groove portion at an upper surface of the pad layer, wherein the pad layer includes a central portion surrounded by the groove portion and an edge portion outside the groove portion;
forming a cover layer on the groove portion of the pad layer and the central portion of the pad layer surrounded by the groove portion;
forming a second insulating layer having a via hole overlapping the pad layer; and
forming a connection portion within the via hole of the second insulating layer,
wherein an outer edge portion of the cover layer is disposed within groove portion, and
a width of the central portion of the pad layer is wider than a width of the groove portion.

13. The manufacturing method of the redistribution substrate of claim 12,
wherein the groove portion is formed using a laser.

14. The manufacturing method of the redistribution substrate of claim 13,
wherein a wavelength of the laser is about 350 nm to about 1,100 nm.

15. The manufacturing method of the redistribution substrate of claim 13,
wherein the laser is a carbon dioxide gas laser (CO₂ Laser).

16. The manufacturing method of the redistribution substrate of claim 12, further comprising:
performing an etching process to remove the seed layer exposed by the pad layer,
wherein, during a time when the seed layer is removed in the etching process, an upper surface of the edge portion of the pad layer exposed by the cover layer is partially etched, thereby increasing a surface roughness of the edge portion of the pad layer compared to a surface roughness of the edge portion before the etching process is performed.

17. The manufacturing method of the redistribution substrate of claim 12,
wherein the forming of the cover layer includes:
forming a blocking layer on the edge portion of the pad layer disposed outside the groove portion, and
performing a plating process to form the cover layer using the blocking layer as a mask.

18. The manufacturing method of the redistribution substrate of claim 17,
wherein the cover layer is disposed on the central portion and at least a portion of the groove portion, and
wherein, when viewed in a plan view, the entirety of the cover layer is within an outer boundary of the groove portion.

19. The manufacturing method of the redistribution substrate of claim 18,
wherein the second insulating layer covers the edge portion of the pad layer, and
wherein the second insulating layer covers the outer edge portion of the cover layer.

20. A semiconductor package comprising:
a first redistribution substrate;
a second redistribution substrate; and
a semiconductor chip disposed between the first redistribution substrate and the second redistribution substrate,
wherein the first redistribution substrate includes
a first insulating layer;
a pad layer disposed on the first insulating layer and including a groove portion, a central portion surrounded by the groove portion, and an edge portion disposed outside the groove portion;
a cover layer disposed on the pad layer, wherein, when viewed in a plan view, the entirety of the cover layer is disposed within an outer boundary of the groove portion;
a second insulating layer disposed on the pad layer and having a via hole overlapping the pad layer; and
a connection portion disposed within the via hole of the second insulating layer,
wherein an outer edge portion of the cover layer is disposed within groove portion, and
wherein a width of the central portion of the pad layer is wider than a width of the groove portion.
